(19) United States
(12) Patent Application Publication
(10) Pub. No.: US 2015/0107619 A1
(43) Pub. Date: Apr. 23, 2015

(54) WAFER PARTICLE REMOVAL

(71) Applicant: Taiwan Semiconductor Manufacturing Company Limited, Hsin-Chu (TW)

(72) Inventors: Jiann Lih Wu, Hsinchu City (TW); He Hui Peng, Changhua City (TW); Jeng-Jyi Hwang, Chu-Tong Town (TW); Chi-Ming Yang, Hsinchu City (TW)

(21) Appl. No.: 14/059,713

(22) Filed: Oct. 22, 2013

(51) Int. Cl. H01L 21/02; H01L 21/67

(52) U.S. Cl. CPC H01L 21/02087; H01L 21/02057; H01L 21/67092
USPC 134/6; 15/77; 451/64; 134/198

(57) ABSTRACT

Among other things, one or more techniques or systems for particle removal from a semiconductor wafer are provided. Particles, contaminating a semiconductor wafer, have the potential to cause defects, such as scratches into a surface of the semiconductor wafer during chemical mechanical polishing or defocusing during a subsequent lithography stage, for the semiconductor wafer. Accordingly, a mechanic particle cleaner component, such as at least one of a sliver brush roller, a pencil brush, a tape polish, a sonic jet, or a liquid spray component, is configured to apply a mechanical force to an edge region of the semiconductor wafer to detach particles. A chemical particle cleaner component is configured to apply a chemical force to the edge region to detach particles. In this way, particles are removed from the semiconductor wafer before or after chemical mechanical polishing.

### BACKGROUND

During fabrication of a semiconductor wafer, chemical mechanical polishing is performed to smooth surfaces of the semiconductor wafer using chemical and mechanical forces. For example, the semiconductor wafer is polished to prepare the semiconductor wafer for a new layer of material. In an example of polishing, the semiconductor wafer is secured to a polishing head configured to polish the semiconductor wafer against a polishing pad. The polishing head applies force to the semiconductor wafer toward the polishing pad during polishing. The polishing head rotates the semiconductor wafer against the polishing pad, which is also rotated, to apply mechanical force to the semiconductor wafer to remove material or even out irregular topography of the semiconductor wafer. In an example, chemicals are applied to the polishing pad during polishing to apply corrosive chemical force to the semiconductor wafer to aid in polishing. If the semiconductor wafer is contaminated with particles before polishing, then such particles can cause defects, such as scratches, on the semiconductor wafer. After polishing, particles, such as polishing by-products or slurry residue, can cause defocusing during a lithography stage or other issues.

### DESCRIPTION OF THE DRAWINGS

FIG. 1 is a flow diagram illustrating a method of removing particles from a semiconductor wafer, according to some embodiments.

FIG. 2 is an illustration of a side view of a semiconductor wafer, according to some embodiments.

FIG. 3A is an illustration of a side view of a mechanical particle cleaner component comprising a sliver brush roller component, according to some embodiments.

FIG. 3B is an illustration of a top down view of a mechanical particle cleaner component comprising a sliver brush roller component, according to some embodiments.

FIG. 4 is an illustration of a side view of a mechanical particle cleaner component comprising a pencil brush component, according to some embodiments.

FIG. 5 is an illustration of a side view of a mechanical particle cleaner component comprising a tape polish component, according to some embodiments.

FIG. 6 is an illustration of a top down view of a mechanical particle cleaner component comprising a sonic jet component, according to some embodiments.

FIG. 7A is an illustration of a top down view of a mechanical particle cleaner component comprising the liquid spray component, according to some embodiments.

FIG. 7B is an illustration of a side view of a mechanical particle cleaner component comprising a liquid spray component, according to some embodiments.

FIG. 8 is an illustration of a chemical particle cleaner component, according to some embodiments.

### DETAILED DESCRIPTION

The claimed subject matter is now described with reference to the drawings, wherein like reference numerals are generally used to refer to like elements throughout. In the following description, for purposes of explanation, numerous specific details are set forth in order to provide an understanding of the claimed subject matter. It is evident, however, that the claimed subject matter can be practiced without these specific details. In other instances, structures and devices are illustrated in block diagram form in order to facilitate describing the claimed subject matter.

One or more techniques or systems for particle removal from a semiconductor wafer are provided. During semiconductor processing, particles, such as leftover chemicals, metal, etch by-products, polishing by-products, or other material, contaminant a semiconductor wafer being processed. During polishing of the semiconductor wafer, such as during chemical mechanical polishing (CMP), the particles have the potential to cause scratches or other defects on the semiconductor wafer. After polishing, the semiconductor wafer becomes contaminated with particles, such as polishing by-products or slurry residue, which have the potential to cause defocusing during a lithography stage or other defects during subsequent processing stages. Accordingly, as provided herein, a mechanical particle cleaner component and a chemical particle cleaner component are used to remove particles from the semiconductor wafer.

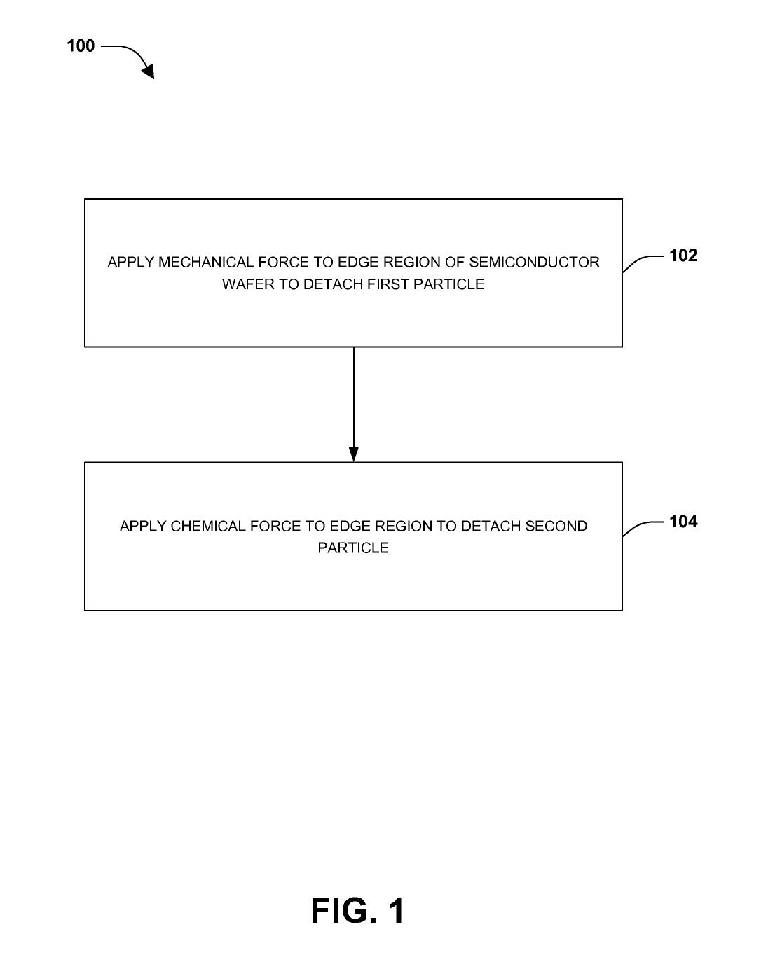

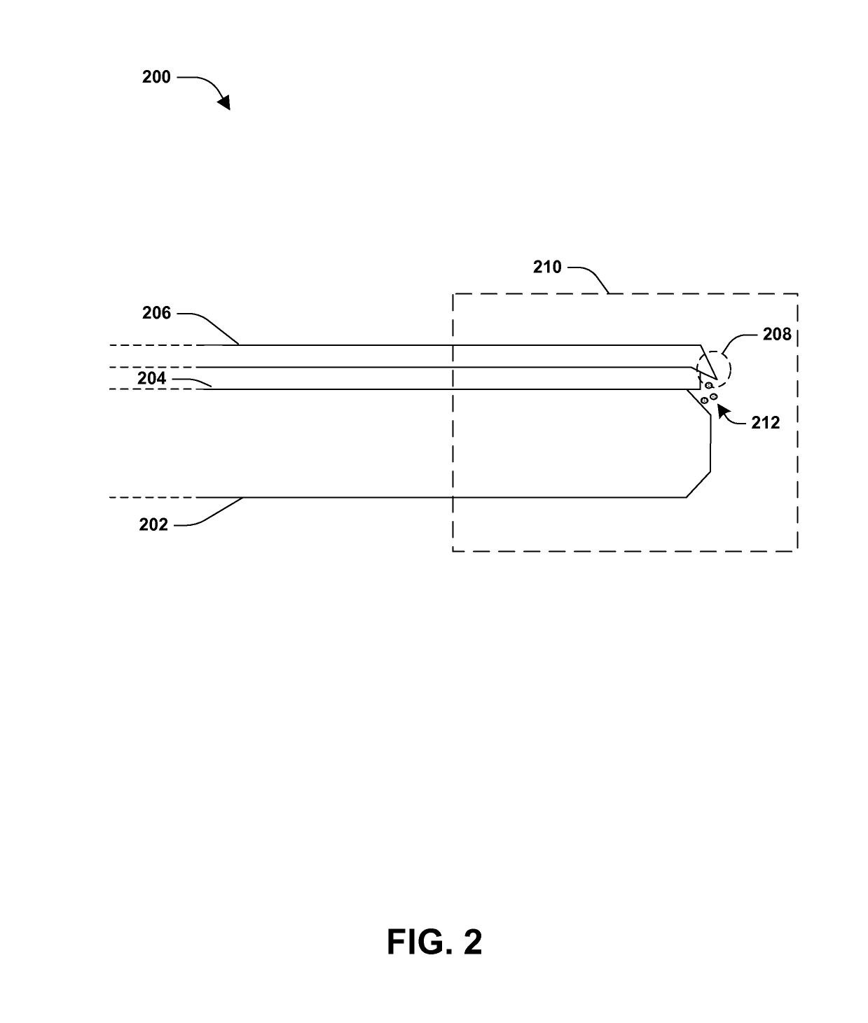

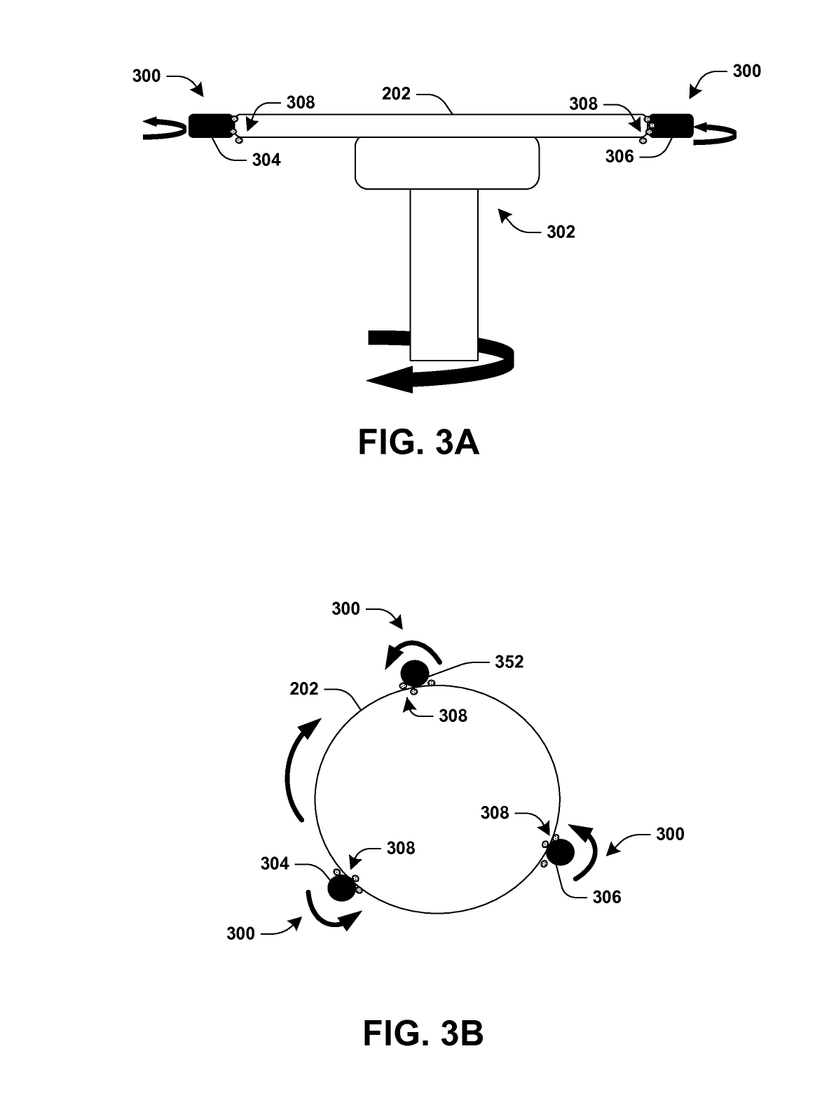

A method 100 of removing particles from a semiconductor wafer is illustrated in FIG. 1, and one or more systems for particle removal from a semiconductor wafer are illustrated in FIGS. 3A-8. A semiconductor wafer 202 comprises an edge region 210, as illustrated in FIG. 2. It is appreciated that the edge region 210 is not limited to the region illustrated, and that the edge region 210 comprises any portion of the semiconductor wafer 202, such as a top wafer surface between a wafer center and a wafer edge of the semiconductor wafer 202, a beveled edge portion of the wafer edge, or any other portion of the semiconductor wafer 202 that becomes contaminated with particles. In an embodiment, one or more deposition layers are formed over the semiconductor wafer 202, such as a first deposition layer 204 and a second deposition layer 206. At least one of the first deposition layer 204 or the second deposition layer 206 comprise a film edge coating overhang 208 that has the potential to produce particles 212 that contaminate the semiconductor wafer 202. Accordingly, at least one of mechanical force or chemical force are applied to the edge region 210 to remove particles from the semiconductor wafer 202.

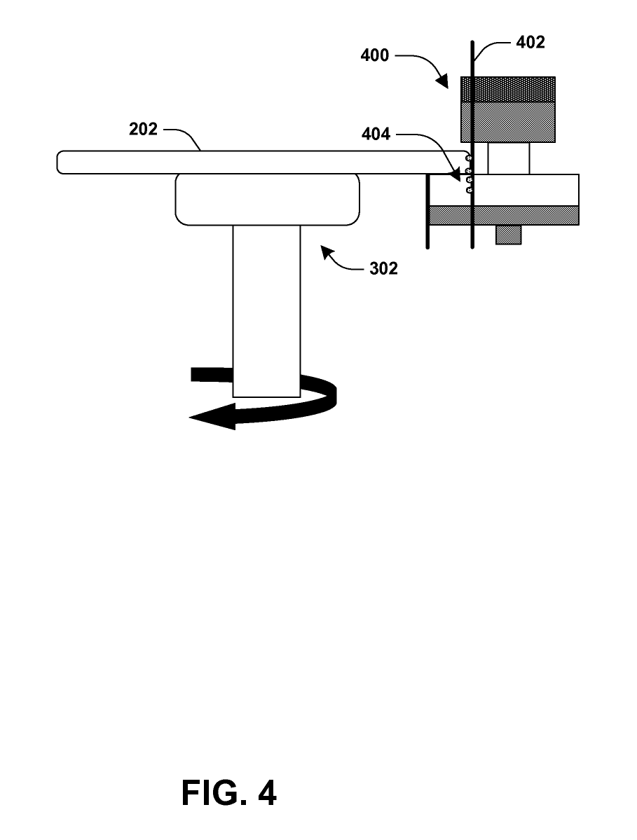

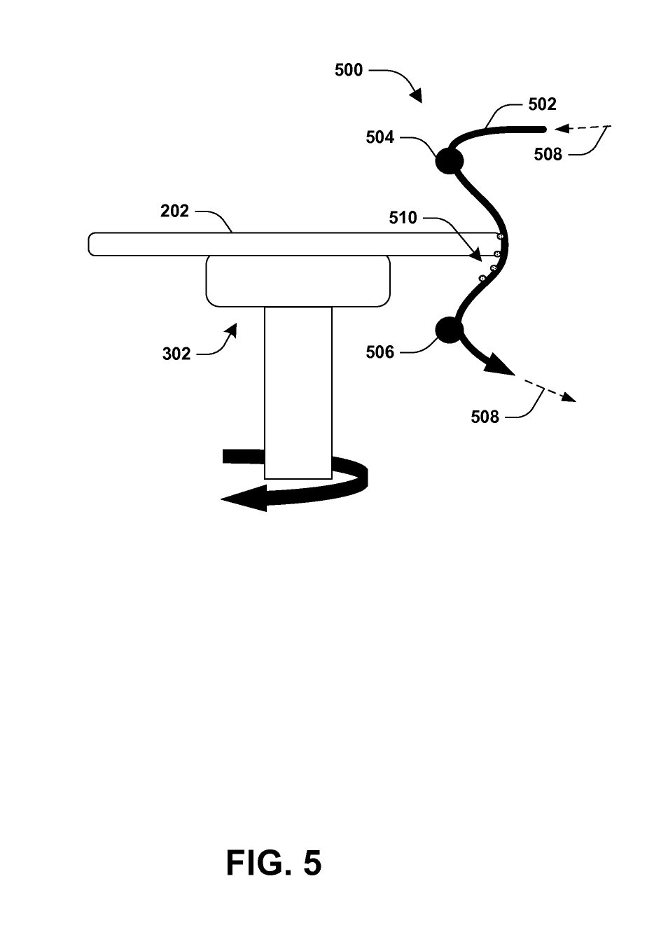

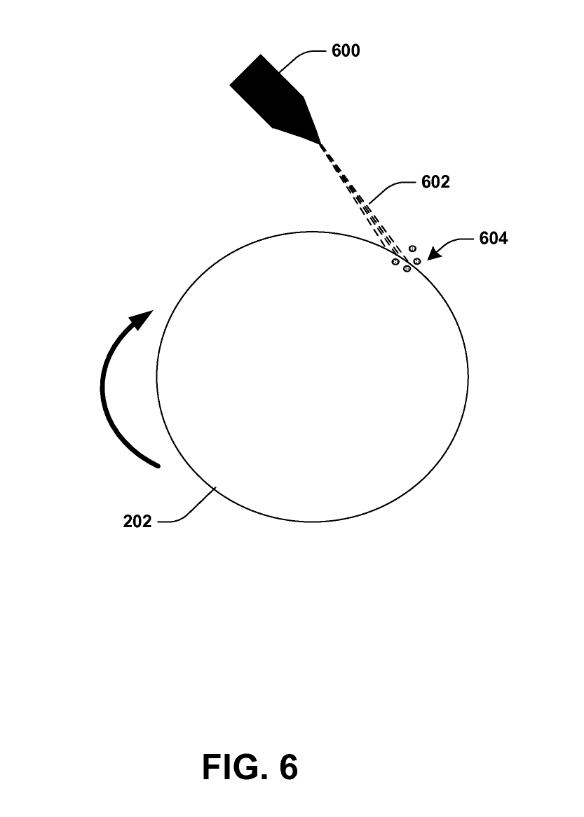

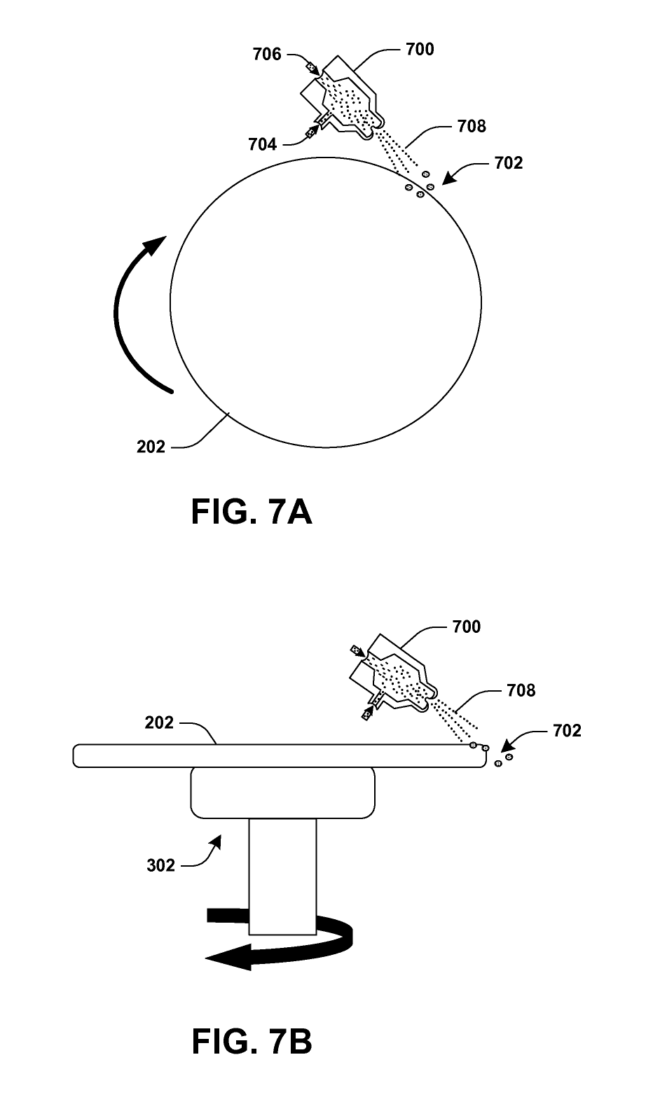

At 102, a mechanical force is applied to the edge region 210 of the semiconductor wafer 202 to detach a particle from the semiconductor wafer 202. In an embodiment, the particle is detached from a beveled edge portion of the edge region. In an embodiment, the mechanical force is applied by a mechanical particle cleaner component, such as one or more of a sliver brush roller component (e.g., FIGS. 3A and 3B), a pencil brush component (e.g., FIG. 4), a tape polish component (e.g., FIG. 5), a sonic jet component (FIG. 6), or a liquid spray component (e.g., FIGS. 7A and 7B). In an embodiment, the mechanical particle cleaner component is configured to detach the particle during a pre-polish phase before chemical mechanical polishing of the semiconductor wafer 202. In an embodiment, the mechanical particle cleaner component is configured to detach the particle during a post-polish phase after chemical mechanical polishing of the semiconductor wafer 202. In an embodiment, the mechanical particle cleaner component is located at a first position within a wafer processing device for particle removal during the pre-polish phase, and is moved to a second position for particle removal during the post-polish phase.

FIG. 3A illustrates a side view of the mechanical particle cleaner component comprising a sliver brush roller component 300. The sliver brush roller component 300 comprises one or more brush rollers, such as a first brush roller 304 and a second brush roller 306. The sliver brush roller component 300 comprises any number of brush rollers, such as a third brush roller 352, illustrated by a top down view of FIG. 3B. The sliver brush roller component 300 is configured to rotate against the edge region 210 of the semiconductor wafer 202 to detach one or more particles 308 from the semiconductor wafer 202. In an embodiment, the semiconductor wafer 202 is mounted to a rotational device 302 that rotates the semiconductor wafer 202 in a first direction against one or more brush rollers, such as against the first brush roller 304 and against the second brush roller 306. In an embodiment, one or more brush rollers, such as the first brush roller 304 and the second brush roller 306 are rotated against the semiconductor wafer 202 in a second direction opposite the first direction. In an embodiment, the sliver brush roller component 300 comprises a polyvinyl alcohol (PVA) brush. In an embodiment, liquid, such as deionized water, is applied to the semiconductor wafer 202 during particle removal by the sliver brush roller component 300 to aid in particle removal.

FIG. 4 illustrates a side view of the mechanical particle cleaner component comprising a pencil brush component 400. The pencil brush component 400 is configured to brush against the edge region 210 of the semiconductor wafer 202 to detach one or more particles 404 from the semiconductor wafer 202. In an embodiment, the rotational device 302 rotates the semiconductor wafer 202 against a pencil brush portion 402 of the pencil brush component 400 to remove the one or more particles 404.

FIG. 5 illustrates a side view of the mechanical particle cleaner component comprising a tape polish component 500. The tape polish component 500 is configured to apply a wafer tape 502 to the edge region 210 of the semiconductor wafer 202 to detach one or more particles 510 from the semiconductor wafer 202. In an embodiment, the tape polish component 500 moves the wafer tape 502 in a direction 508 across the beveled edge portion of the semiconductor wafer 202. In an embodiment, the tape polish component 500 moves the wafer tape 502 through a first tape roller 504 and a second tape roller 506. The first tape roller 504 and the second tape roller 506 are offset from the beveled edge portion so that a pulling force is applied to the wafer tape 502 towards the beveled edge portion. In an embodiment, rotational device 302 rotates the semiconductor wafer 202 against the wafer tape 502. In an embodiment, the wafer tape 502 comprises an abrasive surface, such as a diamond coated surface or other coated surface.

FIG. 6 illustrates a top down view of the mechanical particle cleaner component comprising a sonic jet component 600. The sonic jet component 600 is configured to apply sound waves 602 to the edge region 210 of the semiconductor wafer 202 to detach one or more particles 604 from the semiconductor wafer 202. In an embodiment, the sonic jet component 600 comprise a mega sonic jet that applies a mega sonic force to physically impact the semiconductor wafer 202 or the one or more particles 604 to detach the one or more particles 604 from the semiconductor wafer 202. In an embodiment, a liquid spray component, such as the liquid spray component 700 of FIG. 7A, is configured to apply a liquid, such as deionized water, to the edge region 210 to aid the sonic jet component 600 in detaching the one or more particles 604. In an embodiment, rotational device 302 rotates the semiconductor wafer 202 while the sonic jet component 600 applies sound waves 602 for particle detachment.

FIG. 7A illustrates a top down view, and FIG. 7B illustrates a side view, of the mechanical particle cleaner component comprising the liquid spray component 700. The liquid spray component 700 is configured to apply a liquid 708, such as deionized water, to the edge region 210 of the semiconductor wafer 202 to detach one or more particles 702 from the semiconductor wafer 202. In an embodiment, a liquid source 704 supplies liquid to the liquid spray component 700. In an embodiment, an air source 706 supplies air to the liquid spray component 700. In this way, air pressure is applied to the liquid to increase a force at which the liquid 708 is applied to the wafer edge region 210 and to direct the liquid 708 towards the wafer edge region 210. It is appreciated that the liquid 708 is applied to any portion of the semiconductor wafer 202, such as a wafer surface, to remove particles from the semiconductor wafer 202. In an embodiment, rotational device 302 rotates the semiconductor wafer 202 while the liquid spray component 700 applies the liquid 708 for particle detachment.

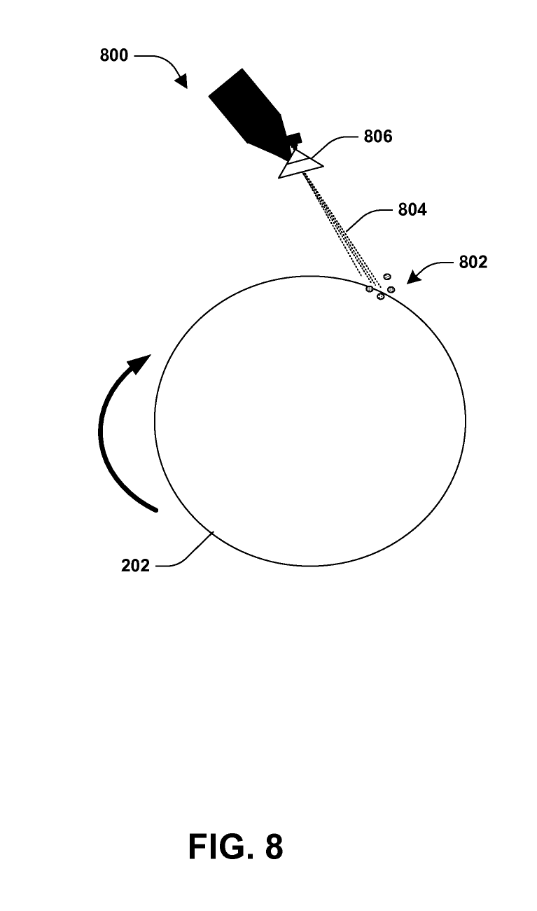

At 104, a chemical force is applied to the edge region 210 of the semiconductor wafer 202. In an embodiment, a chemical particle cleaner component 800 is configured to apply the chemical force, as illustrated in FIG. 8. The chemical particle cleaner component 800 applies a chemical 804 to the edge region 210 of the semiconductor wafer 202 to detach one or more particles 802 from the semiconductor wafer 202. In an embodiment, the chemical 804 comprises at least one of hydrogen fluoride, diluted hydrogen fluoride, or any other chemical suitable for detaching particles. In an embodiment, the chemical particle cleaner component 800 comprises a liquid nozzle component 806 configured to spray a liquid against the chemical 804 to direct the chemical 804 toward the edge region 210. In an embodiment, the liquid comprises deionized water. In an embodiment, the chemical particle cleaner component 800 is configured to detach particles during a pre-polish phase before chemical mechanical polishing of the semiconductor wafer 202. In an embodiment, the chemical particle cleaner component 800 is configured to detach particles during a post-polish phase after chemical mechanical polishing of the semiconductor wafer 202. In an embodiment, the chemical particle cleaner component 800 is located at a first position within the wafer processing device for particle removal during the pre-polish phase, and is moved to a second position for particle removal during the post-polish phase. In an embodiment, rotational device 302 rotates the semiconductor wafer 202 while the chemical particle cleaner component 800 applies the chemical 804 for particle detachment.

It is appreciated that any number or combination of mechanical particle cleaner components or chemical particle cleaner components are used during at least one of the pre-polish phase or the post-polish phase. In an embodiment, at least one of the sliver brush roller component, the pencil brush component, the tape polish component, the sonic jet component, the liquid spray component, or the chemical particle cleaner component is used during the pre-polish phase. Any number, such as one, two, three, four, five, or six, components are used during the pre-polish phase. In an embodiment, at least one of the sliver brush roller component, the pencil brush component, the tape polish component, the sonic jet component, the liquid spray component, or the chemical particle cleaner component is used during the post-polish phase, such as the same or different components used during the pre-polish phase. Any number, such as one, two, three, four, five, or six, components are used during the post-polish phase, which is the same or different as the number used during the pre-polish phase. Components used during the post-polish phase have the same or different locations when used during the pre-polish phase.

According to an aspect of the instant disclosure, a system for particle removal from a semiconductor wafer is provided. The system comprises a mechanical particle cleaner component. The mechanical particle cleaner component is configured to apply a mechanical force to an edge region of the semiconductor wafer to detach a particle from the edge region.

According to an aspect of the instant disclosure, a system for particle removal from a semiconductor wafer is provided. The system comprises a chemical particle cleaner component. The chemical particle cleaner component is configured to apply a chemical to an edge region of the semiconductor wafer to detach a particle.

According to an aspect of the instant disclosure, a method for particle removal from a semiconductor wafer is provided. The method comprises applying a mechanical force to an edge region of a semiconductor wafer to detach a first particle using at least one of a sliver brush roller component, a pencil brush component, a tape polish component, a sonic jet component, or a liquid spray component. The method also comprises applying a chemical force to the edge region to detach a second particle using a chemical particle cleaner component.

Although the subject matter has been described in language specific to structural features or methodological acts, it is to be understood that the subject matter of the appended claims is not necessarily limited to the specific features or acts described above. Rather, the specific features and acts described above are disclosed as embodiment forms of implementing at least some of the claims.

Various operations of embodiments are provided herein. The order in which some or all of the operations are described should not be construed to imply that these operations are necessarily order dependent. Alternative ordering will be appreciated given the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers features, elements, etc. mentioned herein, such as etching techniques, implanting techniques, doping techniques, spin-on techniques, sputtering techniques such as magnetron or ion beam sputtering, growth techniques, such as thermal growth or deposition techniques such as chemical vapor deposition (CVD), physical vapor deposition (PVD), plasma enhanced chemical vapor deposition (PECVD), or atomic layer deposition (ALD), for example.

Further, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application are generally to be construed to mean “one or more” unless specified otherwise or clear from context to be directed to a singular form. Also, at least one of A and B or the like generally means A or B or both A and B. Furthermore, to the extent that “includes”, “having”, “has”, “with”, or variants thereof are used, such terms are intended to be inclusive in a manner similar to “comprising”.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A system for particle removal from a semiconductor wafer, comprising:
a mechanical particle cleaner component configured to:
apply a mechanical force to an edge region of a semiconductor wafer to detach a particle from the edge region.

2. The system of claim 1, the mechanical particle cleaner component configured to detach the particle from a beveled edge of the edge region.

3. The system of claim 1, the mechanical particle cleaner component comprising:
a sliver brush roller component configured to rotate against the edge region to detach the particle.

4. The system of claim 1, the mechanical particle cleaner component comprising:
a pencil brush component configured to brush against the edge region to detach the particle.

5. The system of claim 1, the mechanical particle cleaner component comprising:
a tape polish component configured to apply a wafer tape to the edge region to detach the particle.

6. The system of claim 1, the mechanical particle cleaner component comprising:
a sonic jet component configured to apply sounds waves to the edge region to detach the particle.

7. The system of claim 6, the mechanical particle cleaner component comprising:
a liquid spray component configured to apply a liquid to the edge region to detach the particle.

8. The system of claim 1, the mechanical particle cleaner component comprising:
a liquid spray component configured to apply a liquid to the edge region to detach the particle.

9. The system of claim 8, the liquid spray component configured to utilize air to direct the liquid toward the edge region.

10. The system of claim 1, the mechanical particle cleaner component configured to detach the particle during a pre-polish phase.

11. The system of claim 1, the mechanical particle cleaner component configured to detach the particle during a post-polish phase.

12. The system of claim 1, the mechanical particle cleaner component positioned at a first position within a wafer processing device during a pre-polish phase for particle detaching during the pre-polish phase, and the mechanical particle cleaner component positioned at a second position within the wafer processing device during a post-polish phase for particle detaching during the post-polish phase.

13. The system of claim 1, comprising:
a chemical particle cleaner component configured to:
apply a chemical to the edge region to detach the particle.

14. The system of claim 13, the chemical comprising hydrogen fluoride.

15. The system of claim 13, the chemical particle cleaner component comprising:
a liquid nozzle component configured to spray a liquid against the chemical to direct the chemical toward the edge region.

16. A system for particle removal from a semiconductor wafer, comprising:
a chemical particle cleaner component configured to:
apply a chemical to an edge region of a semiconductor wafer to detach a particle.

17. The system of claim 16, the chemical comprising hydrogen fluoride.

18. The system of claim 16, the chemical particle cleaner component comprising:
a liquid nozzle component configured to spray a liquid against the chemical to direct the chemical toward the edge region.

19. The system of claim 16, comprising:
a mechanical particle cleaner component configured to:
apply a mechanical force to the edge region to detach the particle.

20. A method for particle removal from a semiconductor wafer, comprising:
applying a mechanical force to an edge region of a semiconductor wafer to detach a first particle using at least one of a sliver brush roller component, a pencil brush component, a tape polish component, a sonic jet component, or a liquid spray component; and
applying a chemical force to the edge region to detach a second particle using a chemical particle cleaner component.
